(19) United States
(12) Patent Application Publication
(10) Pub. No.: US 2002/0118773 A1
(43) Pub. Date: Aug. 29, 2002

(54) System and method providing single channel in-phase and quadrature-phase generation

(76) Inventors: David H. Minasi, Fort Lauderdale, FL (US); David J. Graham, Gilbert, AZ (US); Babak Bastani, Weston, FL (US)

Correspondence Address: MOTOROLA, INC, INTELLECTUAL PROPERTY SECTION, LAW DEPT, 8000 WEST SUNRISE BLVD, FT LAUDERDAL, FL, 33322, US

(21) Appl. No.: 09/793,798

(22) Filed: Feb. 26, 2001

(51) Int. Cl. H03D 3/00; H04L 27/14; H04L 27/22; H03K 9/06

(52) U.S. Cl. 375/322; 329/300; 329/304

(57) ABSTRACT

A system is provided which facilitates a single-channel signal processing system. The system includes a single mixing stage, wherein an RF input signal is mixed with an In-Phase and a Quadrature-Phase signal. The mixing stage generates a multiplexed output signal for subsequent signal processing.

### TECHNICAL FIELD

The present invention relates generally to Radio Frequency (RF) down/up conversion systems, and in particular to a system and method providing a single-channel In-Phase and Quadrature-Phase signal processing system.

### BACKGROUND

In many RF systems, such as Direct conversion, Low IF and Zero IF receivers, Direct Launch Transmitters, and Quadrature modulators, In-Phase and Quadrature-Phase (I and Q) signals are generated in order to modulate and demodulate transmitted and received RF signals. Generally, the I and Q signals are derived from a local oscillator circuit and maintain a 90 degree phase relationship between each signal. The I and Q local oscillator signals are then input to separate mixer stages wherein an RF input signal is mixed separately with the I local oscillator signal in a first mixer stage and the Q local oscillator signal is mixed with the RF input signal in a second mixer stage. Separate and parallel I and Q base-band/IF signal paths are then provided for each mixer output wherein intermediate/base-band frequencies are generated and further processed. Each path may also include associated amplifiers, A/D converters, filters and demodulators, for example.

Due to non-idealities and mismatches of analog circuits, generally there are amplitude and phase imbalances between the I and Q paths. Unfortunately, these imbalances can result in signal distortions and degradation of demodulated output signals. Moreover, since two separate paths are maintained, costs are thus increased since the amplifiers, converters, filters, etc. are duplicated. Additionally, power consumption is doubled when supplying power to two independent paths.

Consequently, there is a need for an improved performance down/up conversion system wherein errors due to phase imbalances are mitigated, with costs and operating power consumption reduced.

### BRIEF DESCRIPTION OF THE DRAWINGS

The features of the present invention, which are believed to be novel, are set forth with particularly in the appended claims. The invention, together with further objects and advantages thereof, may best be understood by reference to the following description, taken in conjunction with the accompanying drawings, in the several figures of which like reference numerals identify like elements, and in which:

FIG. 1 is a block diagram of a single-channel architecture providing quadrature down conversion in accordance with the present invention;

FIG. 2 is a schematic block diagram of a single-channel I and Q demodulation system in accordance with the present invention;

FIG. 3 is a schematic block diagram illustrating an alternative I and Q demodulation system in accordance with the present invention; and

FIG. 4 is a flow diagram illustrating a methodology for providing single-channel I and Q phase generation in accordance with the present invention.

### DETAILED DESCRIPTION OF THE INVENTION

While the specification concludes with claims defining the features of the invention that are regarded as novel, it is believed that the invention will be better understood from a consideration of the following description in conjunction with the drawing figures, in which like reference numerals are carried forward.

The present invention relates to a system and method facilitating an improved performance and reduced cost/power In-Phase (I) and Quadrature-Phase (Q) generation/processing system. This is achieved by providing a single-channel system wherein an I and Q local oscillator (LO) signal are concurrently mixed with an RF input signal via a single mixer stage. In contrast to conventional systems wherein two separate mixing stages and associated circuit paths are employed, the present invention utilizes a set of phase clocks to alternately switch the I and Q LO signals at local oscillator inputs of the mixer stage to enable multiplexing and mixing of the I and Q LO signals with the RF input signal. Outputs of the mixer stage thus provide a combination of the I and Q as demodulated Intermediate Frequencies (IF). The outputs from the mixer are de-multiplexed by employing the set of phase clocks to separate the I and Q as IF frequencies after the signals have been concurrently processed via a single-channel conversion system. In this manner, performance is increased since the single-channel system mitigates phase imbalances associated with conventional dual-signal processing paths. Furthermore, cost and power consumption are reduced by eliminating redundant circuits associated with conventional dual-path processing systems.

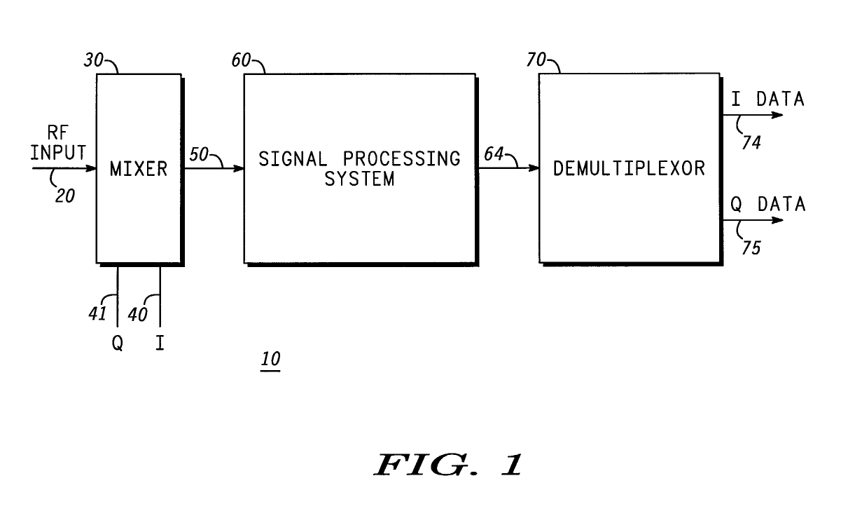

Referring initially to FIG. 1, a single-channel demodulation system 10 illustrates an aspect of the present invention relating to In-Phase and Quadrature-Phase generation associated with IF signal processing. A differential or single ended RF signal 20 is input to a mixer 30. I and Q signals 40 and 41 are mixed with the RF input signal 20 to provide a multiplexed IF signal 50 at the output of the mixer 30. As will be described in more detail below, a set of phase clocks (not shown) are employed to enable switching of the I and Q signals 40 and 41 at the inputs of the mixer 30. In this manner, a second mixer is not required.

The multiplexed IF signal 50 is then input to a signal processing system 60 and converted to a digital output signal 64. For example, the signal processing system 60 can include analog-to-digital converters (A/D) for processing the IF signal 50. The digital output signal 64 is then input to a de-multiplexing system 70 wherein data associated with the I and Q is extracted. The de-multiplexing system 70 provides an I-data output 74 and a Q-data output 75 which is passed to subsequent stages (not shown) for further filtering and demodulating. As will be described in more detail below, the phase clocks are employed by the de-multiplexing system 70 to extract the I-data and Q-data 74 and 75. It is to be appreciated that although system 10 depicts an exemplary IF demodulation and/or down conversion of the RF input 20 to the IF output 50, that single-channel I and Q mixing/processing employed in the present invention can be further utilized in a modulation and/or up conversion system.

By mixing the RF input signal 50 with the I and Q signals 40 and 41 in a single mixer 30, and processing the mixer output 50 via a single processing system 60, the present invention provides many advantages over conventional systems wherein two processing paths are established for the I and Q, respectively. Phase imbalances are mitigated since both the I and Q signals are processed via the same processing system 60 and therefore, are not subject to variable processing conditions. Thus, drift (e.g., voltage, current, and phase drifts related to temperature) associated with conventional dual-path processing systems is mitigated. Moreover, costs and power consumption are reduced since a second mixing stage and a second signal processing stage are not required via the single-channel architecture of the present invention.

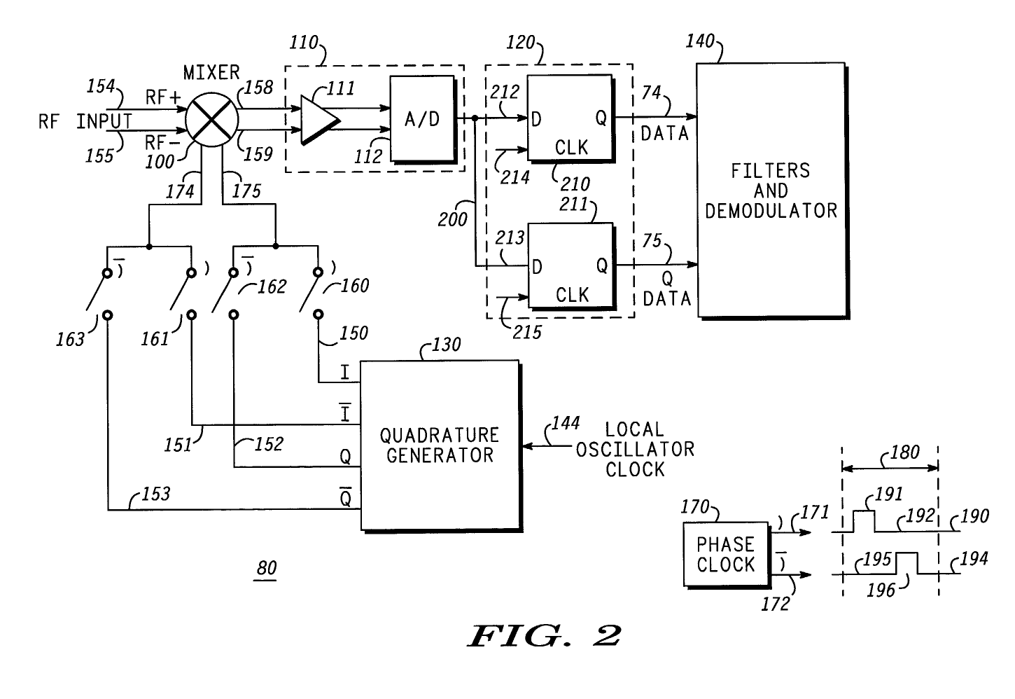

Referring now to FIG. 2, a single-channel In-Phase (I) and Quadrature-Phase (Q) demodulation system 80 is illustrated in accordance with the present invention. The system 80 includes a mixer 100, a signal processing system 110 which can include an amplifier 111 and A/D converter 112, a de-multiplexor 120, and a quadrature generator 130. An associated filter/demodulation system 140 can be provided for subsequent processing of the I and Q data 74 and 75, as described in more detail below.

The quadrature generator 130 receives a local oscillator clock signal 144 and provides a set of differential outputs 150-153. An I-phase output is provided at outputs 150 and 151, wherein a Q-phase output is provided at outputs 152 and 153. The quadrature generator 130 can employ substantially any well-known wave form generation system for providing the I and Q outputs 150-153. For example, digital counters can be employed to count the local oscillator clock signal inputs 144 in order to generate the differential outputs 150-153. It is understood that the I outputs 150 and 151 are complimentary (e.g., about 180 degrees out of phase with respect to each other) as are the Q outputs 152 and 153. It is further understood that the I outputs 150 and 151 are shifted in phase from the Q outputs 152 and 153 by about 90 degrees.

The single-channel architecture of the present invention is enabled by mixing a differential signal RF+ 154 and RF− 155 with the differential I and Q outputs 150-153 via the mixer 100, wherein the mixer 100 generates a set of multiplexed differential IF output signals 158 and 159. This can be achieved via a set of phase-controlled switches 160-163, for example. The phase-controlled switches, which may include MOSFET and/or other high-speed switching technology, can be controlled from a phase clock 170 having a set of clock outputs 171 and 172. The phase clocks 171 and 172, which are shifted with respect to each other, activate the phase-controlled switches 160-163 such that the I and Q outputs 150-153 are input to the mixer 100 at a set of mixer local oscillator inputs 174 and 175.

The phase clocks 171 and 172 thus enable sampling of the I and Q outputs 150-153 onto the mixer inputs 174 and 175, wherein the phase clocks are shifted with respect to each other to enable the I outputs 150-151 to be sampled during a first half period of a sample period and the Q outputs 152-153 to be sampled during a second half of the sample period. It is to be appreciated that a sampling rate (e.g., 1/sample period) as provided by the frequency of the phase clocks 171 and 172 should be higher than the information bandwidth of the RF inputs 154 and 155.

To further illustrate sampling and single-channel mixing of the present invention, phase clock outputs 171 and 172 are depicted over an exemplary sample period 180 having exemplary waveforms 190 and 194. During an active portion 191 of the waveform 190, the waveform 194 is at an inactive portion 195. The active portion 191 of the waveform 190 enables the phase-controlled switches 160 and 161 for example, wherein the inactive portion 195 of waveform 194 de-activates the switches 162 and 163, for example. Thus, during the active portion 191, the I outputs 150 and 151 are provided to the mixer inputs 174 and 175 and are mixed with the RF+ and RF− inputs 154-155 to provide the mixer outputs 158 and 159.

At a later time in the sample period 180, the active portion 191 of waveform 190 becomes inactive at reference numeral 192 and the inactive portion 195 of waveform 194 becomes active at reference numeral 196. During this portion of the sample period 180, the Q outputs 1502-153 are thus provided to the mixer inputs 174 and 175. It is to be appreciated that the phase-clock 170 can be related to and further derived from the local oscillator inputs 144 in order to provide a suitable timing relationship between the I and Q outputs 150-153 and the phase clock outputs 171 and 172. It is further to be appreciated that although the system 80 is described in exemplary terms in relation to differential signals and/or differential signal processing, single ended signals (e.g., RF input, I and Q—without related complimentary signals) and related processing can also be employed in accordance with the present invention.

The mixer outputs 158 and 159, after mixing has occurred with the sampled I and Q outputs 150-153, thus provide a multiplexed IF frequency with both I and Q modulation information. The outputs 158 and 159 are input to the signal processing system 110 to generate a digital output signal 200. The signal processing system 110 can include an amplifier 111 to provide gain/buffering to the outputs 158 and 159, wherein the A/D converter 112 enables conversion of the outputs 158-159 to the digital output 200. It is to be appreciated that the mixer 100, the amplifier 111, and the A/D converter 112 should be of a higher bandwidth than the modulation bandwidth of the RF input signals 154-155 in order to process the multiplexed IF frequencies. For example, a bandwidth of approximately 10 times the RF input signal modulation bandwidth can be suitable.

The signal processing output 200 is then fed to the de-multiplexing system 120 in order to extract the I-data 74 and Q-data 75. For example, the de-multiplexing system 120 can include a first flip-flop 210 for de-multiplexing the I-data 74 and a second flip-flop 211 for de-multiplexing the Q-data 75. As illustrated, this can be achieved by feeding the signal processing system output 200 to respective flip-flop inputs 212 and 213. The phase clock 171 can be utilized to clock the I-data 74 at a clock input 214, wherein the phase clock 172 can be utilized to clock the Q-data 75 at a clock input 215. The I and Q data 74 and 75 can be further processed by the filter/demodulation system 140. The filter/demodulation system 140 can further provide subsequent IF processing wherein lower IF frequencies are desired, and/or can include processing for demodulating the information that was originally modulated into the RF input signals 154 and 155.

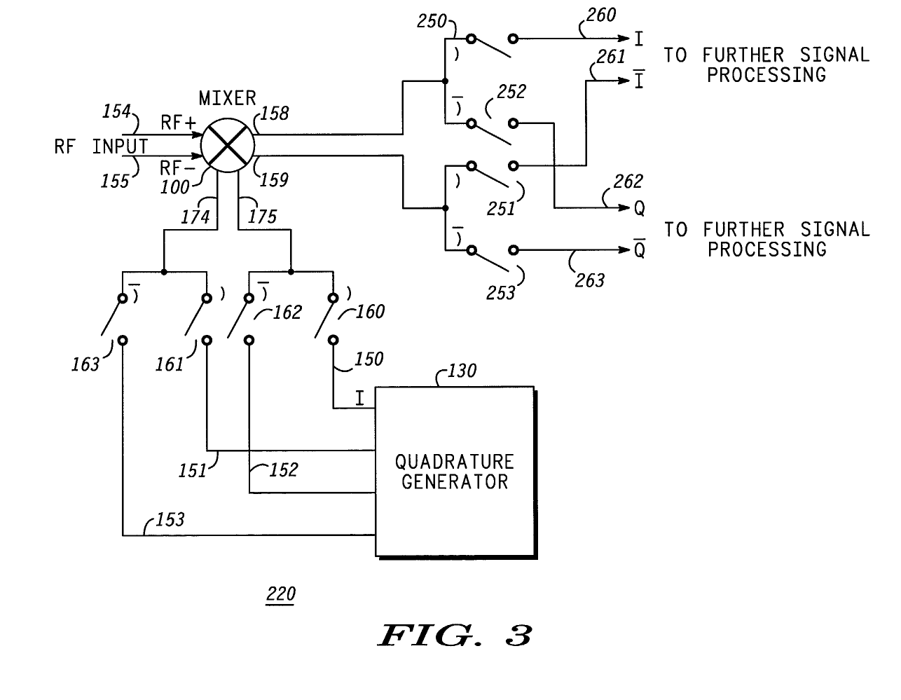

Turning now to FIG. 3, a system 220 illustrates an alternative aspect of the present invention. As described above in relation to FIG. 2 and the single-channel architecture 80, the mixer and subsequent signal processing stage should operate at a higher bandwidth than the modulation bandwidth of the incoming RF input signal. Therefore, the signal processing system should operate at a sufficient clock speed above modulation bandwidth of the RF input signal in order to provide a suitable signal processing bandwidth. At higher speeds however, higher currents can be consumed by the signal processing system. Thus, the system 220 provides an alternative de-multiplexing architecture to enable lower speed/current operation of a signal processing system.

The system 220 architecture includes the single mixer 100 and quadrature generator 130 as described above. The I and Q outputs 150-153 are also sampled at the inputs 174 and 175 respectively, as described above. The mixer outputs 158 and 159 are de-multiplexed via a second set of phase-controlled switches 250-253. When the I outputs 150 and 151 are being input to the mixer 100, the phase switches 250 and 251 are enabled via the phase clock 171 to provide de-multiplexed I outputs 260 and 261. Similarly, when the phase switches 252 and 253 are activated via the phase clock 172, de-multiplexed Q-outputs 262 and 263 are provided. The I and Q outputs can then be fed to separate signal processing systems (not shown) to digitize the I and Q modulation information. Although an additional signal processing system can be employed, the system 220 provides a lower cost system than conventional systems via the single mixer architecture 220. Furthermore, since the I and Q outputs are de-multiplexed at the output of the mixer 100, the resulting signals 260-263 can be processed at a lower bandwidth. Thus, subsequent signal processing systems can be operated at lower speed and power consumption.

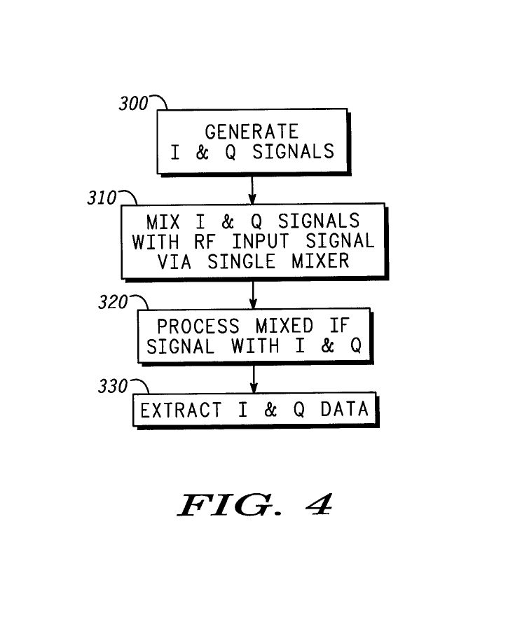

FIG. 4 illustrates a methodology for providing single-channel modulation in accordance with an aspect of the present invention. While, for purposes of simplicity of explanation, the methodology is shown and described as a series of steps, it is to be understood and appreciated that the present invention is not limited by the order of steps, as some steps may, in accordance with the present invention, occur in different orders and/or concurrently with other steps from that shown and described herein. For example, those skilled in the art will understand and appreciate that a methodology could alternatively be represented as a series of interrelated states, such as in a state diagram. Moreover, not all illustrated steps may be required to implement a methodology in accordance with an aspect of the present invention.

The process begins at step 300 in which I and Q signals are generated in accordance with the present invention. This can be achieved, as described above, by providing a waveform generator which is driven from a local oscillator clock, for example. The process proceeds to step 310, in which the I and Q signals from step 300 are mixed with an RF input signal via a single mixer stage to provide a multiplexed IF signal with both I and Q modulation frequencies. This can be achieved, as described above, via a phase clock and phase-controlled switches, for example. At step 320, the multiplexed IF signal is processed via a signal processing system wherein the multiplexed IF signal may be converted to digital format. At step 330, I and Q data is extracted from the converted digital signal at step 320. For example, this can achieved via a de-multiplexing system as described above.

What has been described above includes one or more examples of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications and variations that fall within the spirit and scope of the appended claims. Furthermore, to the extent that the terms “includes” and variations thereof and “having” and variations thereof are used in either the detailed description or the claims, such term is intended to be inclusive in a manner similar to the term “comprising.”

What is claimed is:

1. A system providing a single-channel processing system, comprising:
a single mixing stage, wherein an RF input signal
is mixed with an In-Phase and a Quadrature-Phase signal to provide a multiplexed output signal for subsequent signal processing.

2. The system of claim 1, wherein the In-Phase and Quadrature-Phase signals are provided to the single mixing stage via a phase-controlled switch.

3. The system of claim 2, wherein the phase-controlled switches are controlled via a phase clock for alternating the In-Phase and Quadrature-Phase signals at a set of inputs associated with the single mixing stage.

4. The system of claim 1, further comprising a signal processing system for subsequent signal processing of the multiplexed signal.

5. The system of claim 4, further comprising a de-multiplexing system for extracting IF information associated with the In-Phase and Quadrature-phase signals.

6. The system of claim 1, wherein an output of the single mixing stage is de-multiplexed to enable lower bandwidth IF signal processing.

7. The system of claim 6, wherein the single stage mixing output is de-multiplexed via phase-controlled switches.

8. The system of claim 1, wherein the single mixing stage is applied to at least one of a down conversion and an up conversion signal processing system.

9. A method providing a single-channel processing system, comprising:
generating and In-Phase and a Quadrature-Phase signal; and
mixing the In-Phase and Quadrature-Phase signals with an RF input signal in a single mixing stage to generate a multiplexed output signal.

10. The method of claim 9 further comprising:
processing the multiplexed IF signal via a signal processing system; and
extracting IF information relating to the In-Phase and Quadrature-Phase signals.
